(19) United States
(12) Patent Application Publication
(10) Pub. No.: US 2022/0253097 A1
(43) Pub. Date: Aug. 11, 2022

(54) MOUNTING DOCK WITH MODULE RECEPTACLE AND METHODS OF MAKING AND USING

(71) Applicant: National Products, Inc., Seattle, WA (US)

(72) Inventors: Jeffrey D. Carnevali, Seattle, WA (US); Jacob Parker, Seattle, WA (US); Stefan Michael Gottschalk, Seattle, WA (US)

(21) Appl. No.: 17/174,152

(22) Filed: Feb. 11, 2021

(51) Int. Cl. G06F 1/16

(52) U.S. Cl. CPC G06F 1/1632

(57) ABSTRACT

A mounting dock for an electronic device includes a base configured to fit over at least a portion of a back surface of the electronic device; a tray extending from the base for receiving one side of the electronic device and extending over a portion of the front surface of the electronic device; at least one attachment arm extending from the base opposite the tray and configured to engage a portion of the front surface of the electronic device; and a module receptacle extending from the base and configured to receive and securely store a module that is attachable to the electronic device or a case containing the electronic device.

### FIELD

The present invention is directed to a mounting dock for an electronic device. The present invention is also directed to a mounting dock with a module receptacle.

### BACKGROUND

A case for an electronic device (or the electronic device itself) can include an arrangement for attaching modules or other devices. However, when a user wants to insert the electronic device into a conventional mounting dock, the attached modules or other devices often hinder or prevent the insertion and must be removed. These modules or other devices may be misplaced or may not be easily available for use when removed.

### BRIEF SUMMARY

One embodiment is a mounting dock for an electronic device that includes a base configured to fit over at least a portion of a back surface of the electronic device; a tray extending from the base for receiving one side of the electronic device and extending over a portion of the front surface of the electronic device; at least one attachment arm extending from the base opposite the tray and configured to engage a portion of the front surface of the electronic device; and a module receptacle extending from the base and configured to receive and securely store a module that is attachable to the electronic device or a case containing the electronic device.

In at least some embodiments, the module receptacle includes a cavity configured to receive an attachment element of the module and a floor of the cavity. In at least some embodiments, the module receptacle further includes sidewalls defining the cavity, wherein at least one of the sidewalls is flared outwardly to produce an undercut region between a top of the sidewall and the floor of the cavity. In at least some embodiments, the module receptacle further includes a ridge extending from the floor of the cavity or a detent in the floor of the cavity. In at least some embodiments, the module receptacle further includes a depression in the floor of the cavity or a protrusion extending from the floor of the cavity.

In at least some embodiments, the attachment arm includes a roller configured to engage a front surface of the electronic device when the electronic device is inserted into the mounting dock. In at least some embodiments, the mounting dock further includes a mounting arrangement on the base and configured for attachment to a mount or mounting device. In at least some embodiments, the mounting dock further includes contacts disposed in the tray.

Another embodiment is an arrangement that includes any of the mounting docks described above and a module coupleable to the mounting receptacle of the mounting dock.

In at least some embodiments, the module receptacle includes a cavity and a floor of the cavity and the module includes an attachment element configured to be inserted into the cavity of the module receptacle. In at least some embodiments, both the module receptacle and the attachment element of the module include sidewalls, wherein at least one of the sidewalls is flared outwardly to produce an undercut region. In at least some embodiments, the module receptacle and the attachment element each include a different one of the following: i) a ridge extending from the floor of the cavity or the attachment element or ii) a detent in the floor of the cavity or in the attachment element and configured to mate with the ridge. In at least some embodiments, the module receptacle and the attachment element each include a different one of the following: i) a depression in the floor of the cavity or the attachment element or ii) a protrusion from the floor of the cavity or the attachment element and configured to mate with the depression.

In at least some embodiments, the arrangement further includes a case configured to receive the electronic device and configured for insertion into the mounting dock with the electronic device, the case including an attachment arrangement for attachment of the module to the case when the case is not inserted into the mounting dock. In at least some embodiments, the arrangement further includes the electronic device configured for insertion into the case and for insertion into the mounting dock.

Yet another embodiment is a method of using any of the mounting docks or arrangements described above. The method includes inserting an electronic device into the mounting dock; and attaching a module to the mounting receptacle of the mounting dock.

In at least some embodiments, attaching the module including inserting an attachment element of the module into a cavity of the module receptacle. In at least some embodiments, inserting the attachment element includes interlocking sidewalls of the attachment element with sidewalls of the module receptacle that define the cavity. In at least some embodiments, the module receptacle and the attachment element each include a different one of the following: i) a ridge extending from the floor of the cavity or the attachment element or ii) a detent in the floor of the cavity or in the attachment element and configured to mate with the ridge, wherein attaching the module further includes mating the ridge and the detent. In at least some embodiments, the module receptacle and the attachment element each include a different one of the following: i) a depression in the floor of the cavity or the attachment element or ii) a protrusion extending from the floor of the cavity or the attachment element and configured to mate with the depression, wherein attaching the module further includes mating the protrusion and the depression.

In at least some embodiments, the method further includes, prior to inserting the electronic device into the mounting dock, removing the module from the electronic device or a case disposed on the electronic device. In at least some embodiments, the method further includes removing the module from the module receptacle.

In at least some embodiments, the method further includes removing the electronic device from the mounting dock. In at least some embodiments, the method further includes removing the module from the module receptacle and, after removing the electronic device from the mounting dock, attaching the module to the electronic device or a case disposed on the electronic device.

### BRIEF DESCRIPTION OF THE DRAWINGS

Non-limiting and non-exhaustive embodiments of the present invention are described with reference to the following drawings. In the drawings, like reference numerals refer to like parts throughout the various figures unless otherwise specified.

For a better understanding of the present invention, reference will be made to the following Detailed Description, which is to be read in association with the accompanying drawings, wherein:

FIG. 1A is a schematic perspective back view of one embodiment of an electronic device in a case with a module attached to the case;

FIG. 1B is a schematic perspective back view of the electronic device and case of FIG. 1A with the module detached from the case

FIG. 2A is a schematic perspective back view of a mounting dock with a module receptacle for a module, according to the invention;

FIG. 2B is a schematic perspective top view of the mounting dock and module of FIG. 2A, according to the invention;

FIG. 3A is a schematic perspective top view of the mounting dock and attached module of FIG. 2A with an electronic device and case inserted into the mounting dock, according to the invention;

FIG. 3B is a schematic perspective back view of the mounting dock and detached module of FIG. 2A with the electronic device and case inserted into the mounting dock, according to the invention; and

FIG. 3C is a schematic perspective back view of the mounting dock and attached module of FIG. 2A with the electronic device and case inserted into the mounting dock, according to the invention.

### DETAILED DESCRIPTION

The present invention is directed to a mounting dock for an electronic device. The present invention is also directed to a mounting dock with a module receptacle.

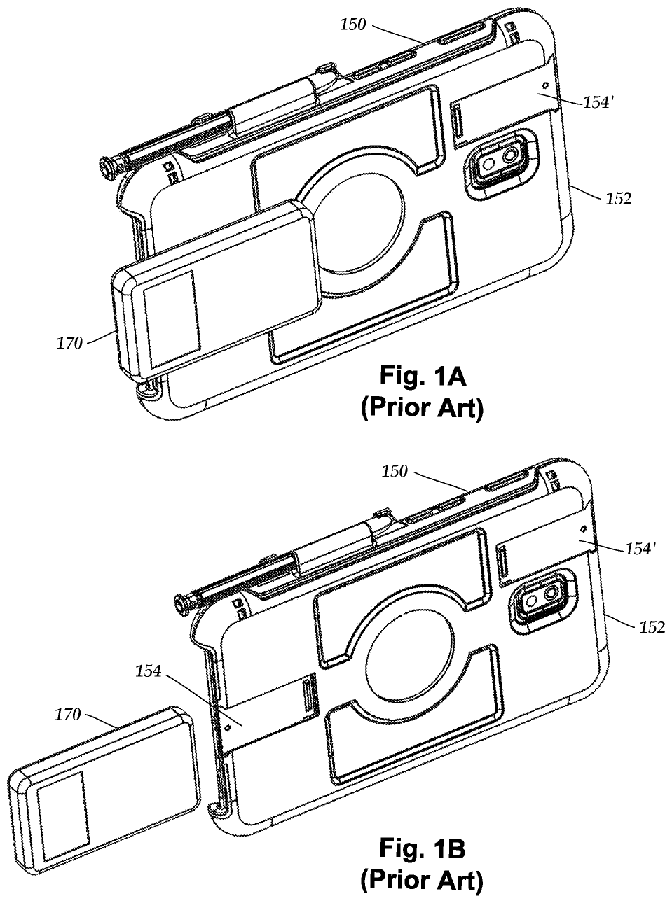

FIGS. 1A and 1B illustrate an electronic device 150 disposed in a case 152 that includes an attachment arrangement 154 for attachment of a module 170. In the illustrated embodiment of FIGS. 1A and 1B, the case 152 includes a second attachment arrangement 154′ for attachment of another module. It will be understood that the electronic device may also or alternatively include the attachment arrangement 154. In at least some embodiments, the module 170 is a device that wirelessly communicates with the electronic device 150 to provide additional functionality. Examples include, but are not limited to, a flash drive or other memory device, a camera, a thermal imaging camera, a laser measurement tool, a battery, a speaker, a chip reader, a lens, a vent, a barcode scanner, a WiFi booster, a payment scanner, a printer, a Bluetooth™ device, or the like or any combination thereof. In other embodiments, the module 170 may be mechanical arrangement, such as a belt clip, a tether, a compact tripod, a selfie stick, an armband, a mobile wallet, or the like, that can provide additional functionality to the case 152. Other examples of modules 170 and cases 152 include the uniVERSE case from Otter Products, Inc. (Fort Collins, Colo.) and associated accessories from Otter Products, Inc. and others, as well as U.S. Pat. No. 9,807,211, incorporated herein by reference in its entirety.

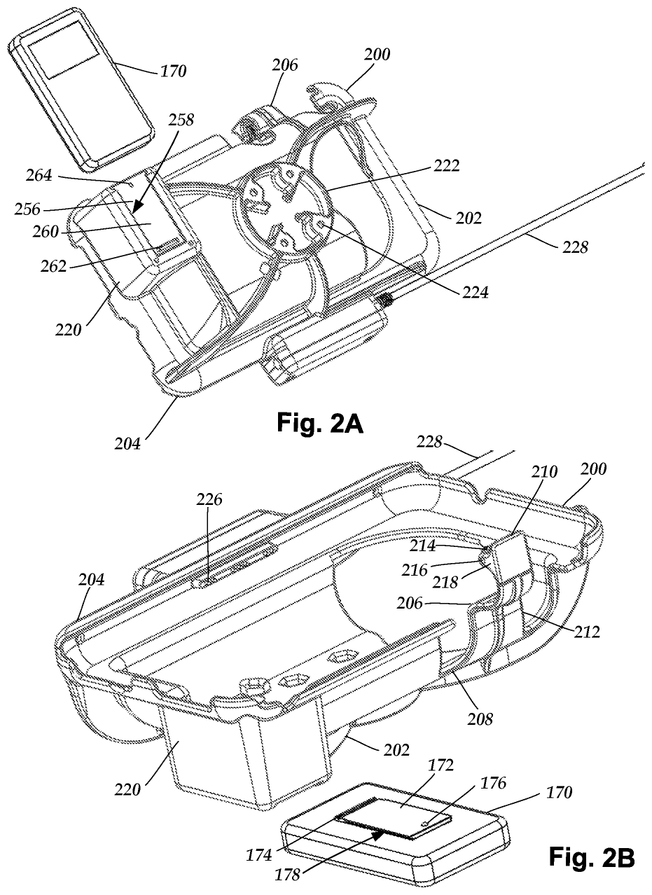

A mounting dock for the electronic device can include a module receptacle of the module. FIGS. 2A and 2B illustrate a mounting dock 200 that is removably attachable to the case 152 and electronic device 154. The mounting dock 200 includes a base 202 and a module receptacle 220 disposed on the base for receiving and securely storing a module 170. In at least some embodiments, the base 202 can includes two, three, four, or more of the module receptacles 220.

The module receptacle 220 defines a cavity 256 sized to receive the correspondingly sized attachment element 172 of the module 260. The cavity 256 has a floor 260 and sidewalls 258 that, in at least some embodiments, flare inwardly to produce undercut regions between the top of the sidewalls and the floor. In at least some embodiments, the attachment element 172 includes similar sidewalls 178 that flare outwardly to produce undercut regions between the top of the sidewalls and the remainder of the module 170. In at least some embodiments, when the attachment element 172 of the module 170 is slid into the cavity 256 of the module receptacle 220, undercut regions of the sidewalls 178 of the attachment element 172 receive the flared portions of the sidewalls 258 of the module receptacle 220 and the flared edges of the sidewalls 178 of the attachment element 172 are received in the undercut regions of the sidewalls 258 of the module receptacle 220 to form an interlocked arrangement for holding the module 170. Other arrangements for retaining the module 170 in the module receptacle 220 can also be used.

In at least some embodiments, the module receptacle 220 includes a ridge 262 that can engage a detent 174 of the attachment element 172 of the module 170 to hinder sliding of the attachment element 172 out of the cavity 256. It will be understood that in alternative embodiments, a detent can be disposed on the module receptacle 220 and a ridge on the attachment element 172. The engagement of the ridge 262 and the detent 174 can be released by the user applying force to slide the module 170 away from the module receptacle 220.

In at least some embodiments, there is a protrusion 176 (FIG. 2B) on the attachment element 172 of the module and a corresponding optional depression 264 in the floor 260 of the cavity 256 of the module receptacle 220. When the attachment element 172 is fully disposed in the cavity 256, the protrusion 176 fits into the depression 264 to hinder sliding of the attachment element 172 out of the cavity 256. It will be understood that the protrusion can instead be positioned within the cavity 256 and the depression can be positioned on the attachment element 172. It will also be recognized that there may be multiple protrusions and depressions. The engagement of the depression 264 and the protrusion 176 can be released by the user applying force to slide the module 170 away from the module receptacle 220.

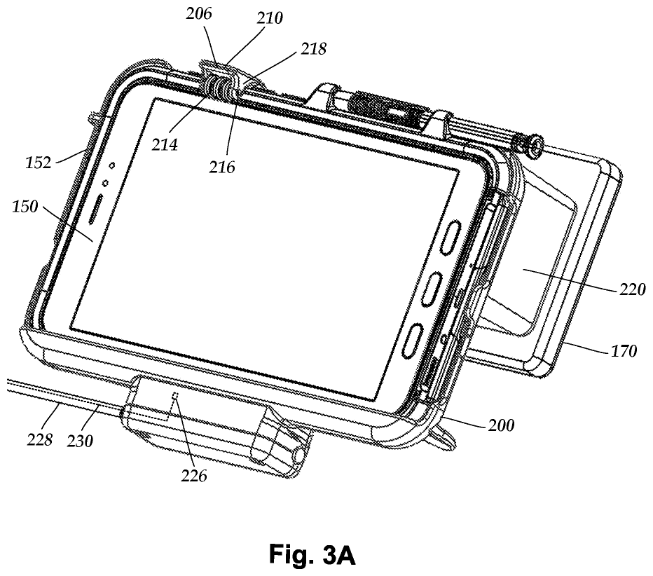

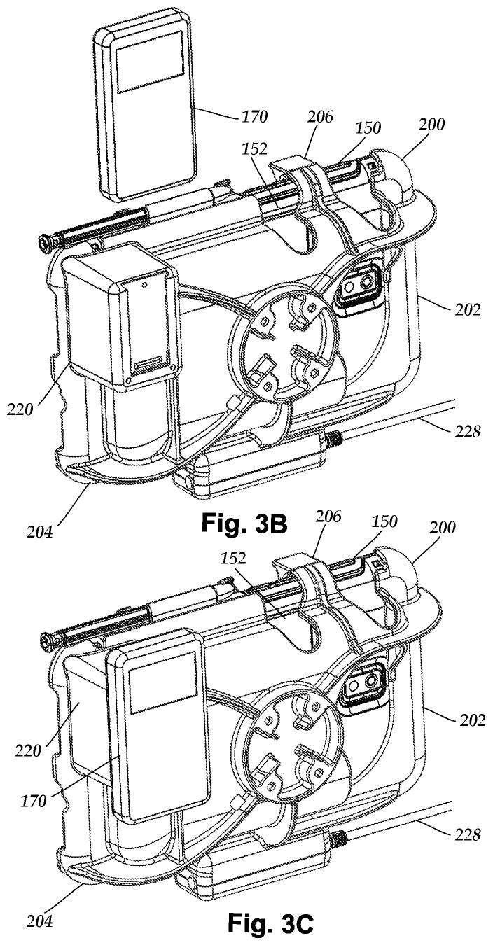

In at least some embodiments, the mounting dock 200 also includes a tray 204 extending from the base 202 for receiving one side of the case 152 and electronic device 154 and extending over a portion of the front surface of the electronic device, as illustrated in FIGS. 3A, 3B, and 3C. In at least some embodiments, the mounting dock includes one or more contacts 226 disposed in the tray 204 and configured to couple to contacts on the case 152 or electronic device 150. The contacts 226 may be suitable for delivering power, data, or the like to the electronic device 150. Any type of contact 226 can be used including, but not limited to, stationary contacts, pogo pins, other movable contacts, pins, contacts on one or more male or female connectors, or the like or any combination thereof. The contacts 226 are coupled to wires 230 (FIG. 3A—only one of which is shown) or other conductors that are carried, in part, by a cord 228 that extends from the remainder of the mounting dock 200. The cord 228 may have a connector at the other end or may be hardwired or hardwireable into another device that can provide the power, data, or the like.

In at least some embodiments, the mounting dock 200 also includes an attachment arm 206 extending from the base for attaching the mounting dock to the case 152. The attachment arm 206 has a back cover engagement portion 208, a front cover engagement portion 210, and a cover width portion 212 extending between the back cover and front cover engagement portions. In at least some embodiments, the back cover and front cover engagement portions 208, 210 are arranged to fit snugly on the case 152 with the electronic device 154 disposed therein to retain the mounting dock 200 on the case 152. In at least some embodiments, the front cover engagement portion 210 includes a roller 214 (FIG. 3) which can roll on an axle 216 held by two legs 218 to facilitate attachment of the mounting dock 200 to the case 152.

In at least some embodiments, the mounting dock 200 can have attached or attachable one or more accessories, such as a mount, that can be attached to a mounting arrangement 222 which includes multiple attachment apertures 224 for receiving a fastener to attach the mount to the mounting arrangement. The mount can be any suitable mount that can be attached to a mounting device. Non-limiting examples of mounts and mounting devices can be found at, for example, U.S. Pat. Nos. 5,845,885; 6,561,476; 7,320,50; 7,997,554; 8,454,178; 8,505,861; 9,831,904; RE42,060; RE42,581; and RE43,806, all of which are incorporated herein by reference in their entireties.

In use, the electronic device (with or without the case) can be inserted into the mounting dock and the module can be attached to the mounting receptacle of the mounting dock. If the module is attached to the electronic device or case, the module is removed from the electronic device or case prior to insertion of the electronic device into the mounting dock.

In at least some embodiments, attaching the module including inserting the attachment element of the module into the cavity of the module receptacle. In at least some embodiments, inserting the attachment element includes interlocking the sidewalls of the attachment element with the sidewalls of the module receptacle, as described above. In at least some embodiments, the module receptacle and the attachment element each include a different one of the following: i) a ridge extending from the floor of the cavity or the attachment element or ii) a detent in the floor of the cavity or in the attachment element and attaching the module includes mating the ridge and the detent. In at least some embodiments, the module receptacle and the attachment element each include a different one of the following: i) a depression in the floor of the cavity or the attachment element or ii) a protrusion extending from the floor of the cavity or the attachment element and attaching the module includes mating the protrusion and the depression.

The electronic device can be removed from the mounting dock. The module can also be removed from the module receptacle and, optionally, attached to the electronic device or a case disposed on the electronic device.

The above specification provides a description of the manufacture and use of the invention. Since many embodiments of the invention can be made without departing from the spirit and scope of the invention, the invention also resides in the claims hereinafter appended.

What is claimed as new and desired to be protected by Letters Patent of the United States is:

1. A mounting dock for an electronic device, the mounting dock comprising:
a base configured to fit over at least a portion of a back surface of the electronic device;
a tray extending from the base for receiving one side of the electronic device and extending over a portion of the front surface of the electronic device;
at least one attachment arm extending from the base opposite the tray and configured to engage a portion of the front surface of the electronic device; and
a module receptacle extending from the base and configured to receive and securely store a module that is attachable to the electronic device or a case containing the electronic device.

2. The mounting dock of claim 1, wherein the module receptacle comprises a cavity configured to receive an attachment element of the module and a floor of the cavity.

3. The mounting dock of claim 2, wherein the module receptacle further comprises sidewalls defining the cavity, wherein at least one of the sidewalls is flared outwardly to produce an undercut region between a top of the sidewall and the floor of the cavity.

4. The mounting dock of claim 2, wherein the module receptacle further comprises a ridge extending from the floor of the cavity.

5. The mounting dock of claim 2, wherein the module receptacle further comprises a depression in the floor of the cavity.

6. The mounting dock of claim 1, wherein the attachment arm comprises a roller configured to engage a front surface of the electronic device when the electronic device is inserted into the mounting dock.

7. The mounting dock of claim 1, further comprising a mounting arrangement on the base and configured for attachment to a mount or mounting device.

8. The mounting dock of claim 1, further comprising contacts disposed in the tray.

9. An arrangement, comprising:
the mounting dock of claim 1; and
a module coupleable to the mounting receptacle of the mounting dock.

10. The arrangement of claim 9, wherein the module receptacle comprises a cavity and a floor of the cavity and the module comprises an attachment element configured to be inserted into the cavity of the module receptacle.

11. The arrangement of claim 10, wherein both the module receptacle and the attachment element of the module comprise sidewalls, wherein at least one of the sidewalls is flared outwardly to produce an undercut region.

12. The arrangement of claim 10, wherein the module receptacle and the attachment element each comprise a different one of the following: i) a ridge extending from the floor of the cavity or the attachment element or ii) a detent in the floor of the cavity or in the attachment element and configured to mate with the ridge.

13. The arrangement of claim 10, wherein the module receptacle and the attachment element each comprise a different one of the following: i) a depression in the floor of the cavity or the attachment element or ii) a protrusion from the floor of the cavity or the attachment element and configured to mate with the depression.

14. The arrangement of claim 9, further comprising a case configured to receive the electronic device and configured for insertion into the mounting dock with the electronic device, the case comprising an attachment arrangement for attachment of the module to the case when the case is not inserted into the mounting dock.

15. The arrangement of claim 14, further comprising the electronic device configured for insertion into the case and for insertion into the mounting dock.

16. A method of using the mounting dock of claim 1, the method comprising:
inserting an electronic device into the mounting dock; and
attaching a module to the mounting receptacle of the mounting dock.

17. The method of claim 16, wherein attaching the module comprising inserting an attachment element of the module into a cavity of the module receptacle.

18. The method of claim 17, wherein inserting the attachment element comprises interlocking sidewalls of the attachment element with sidewalls of the module receptacle that define the cavity.

19. The method of claim 17, wherein the module receptacle and the attachment element each comprise a different one of the following: i) a ridge extending from the floor of the cavity or the attachment element or ii) a detent in the floor of the cavity or in the attachment element and configured to mate with the ridge, wherein attaching the module further comprises mating the ridge and the detent.

20. The method of claim 17, wherein the module receptacle and the attachment element each comprise a different one of the following: i) a depression in the floor of the cavity or the attachment element or ii) a protrusion extending from the floor of the cavity or the attachment element and configured to mate with the depression, wherein attaching the module further comprises mating the protrusion and the depression.
